(19) United States
(12) Patent Application Publication
(10) Pub. No.: US 2018/0083152 A1
(43) Pub. Date: Mar. 22, 2018

(54) CRYSTALLINE SILICON SOLAR CELL MODULE AND MANUFACTURING METHOD FOR SAME

(71) Applicant: KANEKA CORPORATION, Osaka-shi, Osaka (JP)

(72) Inventors: Kunta YOSHIKAWA, Settsu-shi (JP); Toru TERASHITA, Settsu-shi (JP); Kunihiro NAKANO, Settsu-shi (JP); Hayato KAWASAKI, Settsu-shi (JP); Katsunori KONISHI, Settsu-shi (JP)

(21) Appl. No.: 15/579,387

(22) PCT Filed: Jun. 15, 2016
(86) PCT No.: PCT/JP2016/067841

§ 371 Date: Dec. 4, 2017

(30) Foreign Application Priority Data
Jun. 17, 2015 (JP) 2015-122458

(51) Int. Cl. H01L 31/05; H01L 31/0747; H01L 31/0224

(52) U.S. Cl. CPC H01L 31/0508; H01L 31/022475; H01L 31/0747

(57) ABSTRACT

A crystalline silicon solar cell module includes a crystalline silicon solar cell and an interconnector. The interconnector is electrically connected to the crystalline silicon solar cell. The crystalline silicon solar cell includes a photoelectric conversion section that has a first surface and a second surface opposite to the first surface. The crystalline silicon solar cell also includes a plurality of first finger electrodes arranged side by side on the first surface of the photoelectric conversion section. The crystalline silicon solar cell further includes a first insulating layer over the first surface of the photoelectric conversion section and the first finger electrodes. The interconnector extends across the plurality of first finger electrodes and electrically connects the first finger electrodes. The first insulating layer has an opening through which the first finger electrodes and the interconnector are electrically connected.

### TECHNICAL FIELD

The present invention relates to a crystalline silicon solar cell module, and a method for manufacturing the crystalline silicon solar cell module.

### BACKGROUND ART

Generally, on a light-receiving surface of a solar cell, a grid-shaped metal electrode including a finger electrode is formed for collecting a current from a photoelectric conversion section, and a bus bar electrode is formed for collecting the current from the finger electrode to feed the current to an interconnector such as a tab line. In a solar cell module in which a plurality of solar cells are connected, an interconnector serves to electrically connect (interconnect) electrodes in solar cells arranged adjacent to one another, and extract a current to outside.

Patent Document 1 discloses a solar cell in which a grid-shaped metal electrode including a finger electrode and a bus bar electrode is formed on a surface of a photoelectric conversion section, and a silicon oxide insulating film is provided on the photoelectric conversion section at least a region where the metal electrode is not formed. A tab line as an interconnector is soldered onto the bus bar electrode in the solar cell to establish interconnection. Patent Document 1 suggests that by providing an insulating layer on a surface of the photoelectric conversion section, favorable alkali barrier property is exhibited to attain high reliability.

Regarding a crystalline silicon solar cell, there are problems that an electrode material such as a silver paste to be used for a metal electrode is expensive, and that light utilization efficiency is reduced due to a shadowing loss of a light-receiving surface by the metal electrode. A tab line as an interconnector usually has a width of about 0.8 to 2 mm, and a bus bar electrode to be connected to the tab line has a width comparable to that of the tab line. When the width of each of the tab line and the bus bar electrode is decreased to reduce an electrode area, the electrode material cost and the shadowing loss can be reduced. However, a decrease in the electrode width causes an increase of line resistance and contact resistance, leading to deterioration of conversion characteristics.

A smart wire technology (SWT) system has been proposed as an interconnection method capable of decreasing the area of a metal electrode. For example, Patent Document 2 discloses a solar cell module in which wire-shaped interconnectors are connected so as to orthogonally cross finger electrodes at intervals of 5 to 15 mm.

In the SWT system, a bus bar is not formed on a photoelectric conversion section of a solar cell, a metal wire as an interconnector is thermally press-bonded to a finger electrode by thermocompression etc. to establish interconnection. The width (diameter) of a wire to be used in SWT is several hundreds of micrometers (pm), and is smaller than the width (diameter) of a conventional interconnector such as a tab line. Thus, even when the arrangement interval of interconnectors is reduced, and the number of interconnectors provided on a cell is increased, the shadowing loss can be reduced as compared to interconnection by a tab line. Reduction of the arrangement interval of interconnectors decreases the effective length of a finger electrode (distance from the closest interconnector), and therefore even when the number of finger electrodes and the electrode width are decreased, a current loss resulting from line resistance hardly occurs. Thus, in the SWT system, a bus bar electrode is unnecessary, and the area of a finger electrode can be decreased, so that the electrode material cost and the shadowing loss can be reduced.

### PRIOR ART DOCUMENTS

### Patent Documents

Patent Document 1: Japanese Patent Laid-open Publication No. 2006-100522

Patent Document 2: Japanese Patent Laid-open Publication No. 2014-146697

### SUMMARY OF THE INVENTION

### Problems to be Solved by the Invention

Reduction of electrode material cost, and improvement of the power generation amount due to reduction of the shadowing loss etc. can be expected by an interconnection system in which a finger electrode in a solar cell is connected by a wire-shaped interconnector, but some problems remain in practical use of this interconnection system. One of the problems is associated with long-term reliability of a module.

In view of the situations described above, an object of the present invention is to provide a solar cell module having a small optical loss caused by an interconnector, and excellent reliability.

### Means for Solving the Problems

The present inventors have conducted studies, and resultantly found that a solar cell module having excellent reliability is obtained by providing an insulating layer so as to cover the whole surface of a photoelectric conversion section and a metal electrode, locally forming an opening in the insulating layer between the metal electrode and an interconnector, and connecting the metal electrode and the interconnector through the opening.

A crystalline silicon solar cell module of the present invention includes a crystalline silicon solar cell, and an interconnector electrically connected to the crystalline silicon solar cell. The crystalline silicon solar cell includes a plurality of finger electrodes arranged side by side in parallel on a first principal surface of a photoelectric conversion section, and has an insulating layer disposed so as to cover the first principal surface of the photoelectric conversion section and the finger electrodes. Preferably, an insulating layer is disposed on a second principal surface of the photoelectric conversion section and on the finger electrodes on the second principal surface.

The interconnector has a width of 50 μm or more and less than 400 μm, and is arranged extending across a plurality of finger electrodes to electrically connect them. At a part where the finger electrode and the interconnector cross each other, an opening section is formed in the insulating layer disposed between the finger electrode and the interconnector, and the finger electrode and the interconnector are electrically connected through the opening section. Preferably, the finger electrode and the interconnector are electrically connected through a metallic material filled into the opening section of the insulating layer.

For example, by bringing the interconnector into contact with the top of the insulating layer in interconnection, the opening section can be selectively formed at a part where the finger electrode and the interconnector cross each other. By heating the interconnector with the interconnector being in contact with the top of the insulating layer, the opening section may be selectively formed at a part where the finger electrode and the interconnector cross each other.

In one embodiment of the solar cell module of the present invention, the interconnector includes a core material and a low-melting-point material layer. Preferably, the low-melting-point material layer is disposed at a part of the interconnector which is in contact with the insulating layer, i.e., a part of the interconnector which is electrically connected with the finger electrode through the opening section. The interconnector having the low-melting-point material layer is heated to melt the metallic material as a constituent component of the low-melting-point material layer, whereby the opening section of the insulating layer is filled with a metallic material that forms a low-melting-point metallic material layer, or an alloy of a metallic material that forms the low-melting-point metallic material layer and a metallic material that forms the finger electrode. The opening section of the insulating layer may be filled with the metallic material by electroplating.

### Effect of the Invention

According to the present invention, a solar cell module having excellent power generation characteristics and durability can be obtained.

### BRIEF DESCRIPTION OF THE DRAWINGS

FIG. 1 is a schematic sectional view showing one embodiment of the solar cell module.

FIG. 2 is a schematic sectional view showing one embodiment of the solar cell.

FIG. 3A is a schematic plan view showing one embodiment of the solar cell before formation of the insulating layer.

FIG. 3B is a schematic plan view showing one embodiment of the solar cell before formation of the insulating layer.

FIG. 3C is a schematic plan view showing one embodiment of the solar cell before formation of the insulating layer.

FIG. 4 is a schematic plan view of the solar cell after connection of an interconnector.

FIG. 5 is a schematic plan view of the solar cell after connection of an interconnector.

FIG. 6A is a schematic sectional view showing one embodiment of the base with wiring.

FIG. 6B is a schematic sectional view showing one embodiment of the base with wiring.

FIG. 7 is a conceptual view showing arrangement of interconnectors.

### DESCRIPTION OF EMBODIMENTS

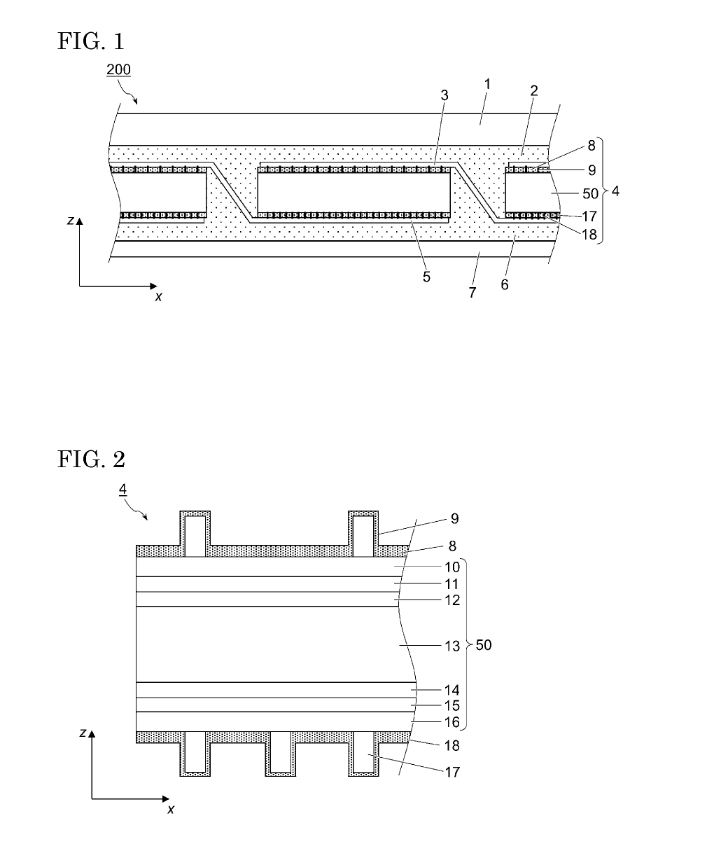

As shown in FIG. 1, a crystalline silicon solar cell module of the present invention includes a crystalline silicon solar cell 4, and interconnectors 3 and 5 electrically connected to the crystalline silicon solar cell. The crystalline silicon solar cell 4 includes finger electrodes 9 and 17, respectively, on both surfaces of the photoelectric conversion section 50.

In the description below, a first principal surface and a second principal surface correspond to a light-receiving surface and a back surface, respectively. The first principal surface and the second principal surface may be a back surface and a light-receiving surface, respectively. The solar cell module in FIG. 1 includes a light-receiving-side protecting member 1, an encapsulant 2, a first interconnector 3, a crystalline silicon solar cell 4, a second interconnector 5, an encapsulant 6 and a back sheet 7 in this order from the light-receiving-side.

[Crystalline Silicon Solar Cell]

For the crystalline silicon solar cell 4, one including a crystalline silicon substrate and being configured to be connected by an interconnector is used. FIG. 2 is a schematic sectional view showing one embodiment of the solar cell before the interconnector is mounted.

(Photoelectric Conversion Section)

The photoelectric conversion section 50 of the solar cell 4 includes a crystalline silicon substrate 13. The crystalline silicon substrate may be either of a single-crystalline silicon substrate and a polycrystalline silicon substrate. Preferably, a surface of the crystalline silicon substrate on the light-receiving-side has concave and convex irregularities with a height of about 1 to 10 μm. When the light-receiving surface has concave and convex irregularities, the light-receiving area increases, and the reflectance decreases, so that optical confinement efficiency is improved. The back-side of the crystalline silicon substrate may also have concave and convex irregularities.

The solar cell 4 shown in FIG. 2 is a so called heterojunction solar cell. The solar cell 4 includes a light-receiving-side insulating layer 8 (first insulating layer), a light-receiving-side finger electrode 9 (first finger electrode), a light-receiving-side transparent electrode layer 10 (first transparent electrode layer), a light-receiving-side conductive silicon layer 11 (first conductive silicon layer), a light-receiving-side intrinsic silicon layer 12 (first intrinsic silicon layer), a crystalline silicon substrate 13, a back-side intrinsic silicon layer 14 (second intrinsic silicon layer), a back-side conductive silicon layer 15 (second conductive silicon layer), a back-side transparent electrode layer 16 (second transparent electrode layer), a back-side finger electrode 17 (second finger electrode) and a back-side insulating layer 18 (second insulating layer) in this order from the light-receiving surface.

In the heterojunction solar cell, a p-type or n-type single-crystalline silicon substrate is used as a crystalline silicon substrate 13. An n-type single-crystalline silicon substrate is preferable because of its long carrier life. The first conductive silicon layer 11 on the light-receiving surface and the second conductive silicon layer 15 on the back surface of the silicon substrate 13 have different conductivity-types, where one of the conductive silicon layers has p-type conductivity, and the other has n-type conductivity.

(Metal Electrode)

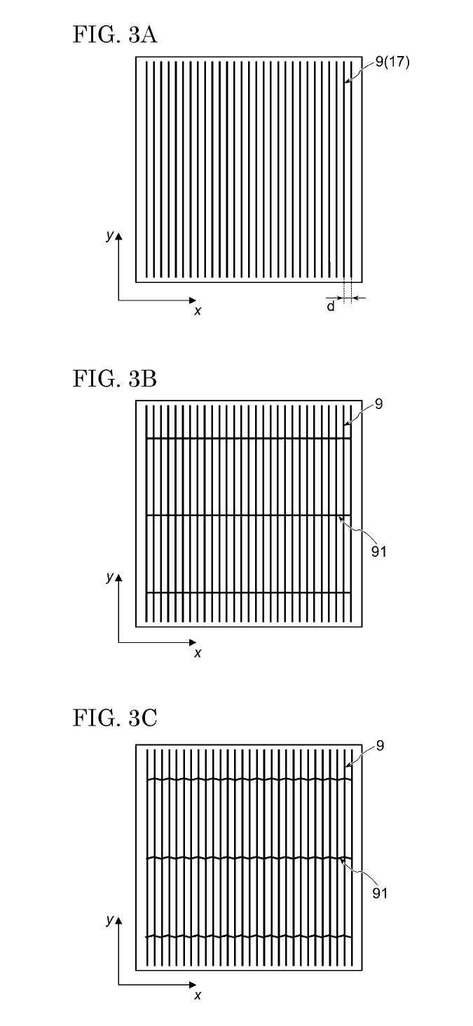

The metal electrode provided on the light-receiving surface and the back surface includes a plurality of finger electrodes 9 and 17 arranged in parallel as shown in FIG. 3A. The finger electrodes 9 and 17 can be formed by printing of an electroconductive paste containing metal particles, a plating method or the like. Examples of the metal particles in the electroconductive paste include Ag particles, and Ag-covered Cu particles. Examples of the metal of the plated electrode include Cu, Ni, Ag and Sn.

The finger electrode may be a single layer, or may have a plurality of layers. For example, a metal thin-film composed of Ag, Cu, Ni, NiCu or the like, or an electroconductive paste layer with a small thickness, or the like may be formed as a seed layer on a surface of the photoelectric conversion section (transparent electrode layer 10 or 16), followed by forming a plated layer thereon by electroplating. The seed electrode layer may be formed by plating.

The width of the finger electrode is preferably 15 to 80 μm, and more preferably 25 to 50 μm. When the width of the finger electrode is in the above-mentioned range, conductivity can be secured and the shadowing loss can be reduced. The interval d between adjacent finger electrodes may be set so as to attain a maximum power generation amount with consideration given to influences of the shadowing loss, line resistance and so on. The distance d may be within a range of, for example, about 0.3 to 2 mm. The interval between adjacent electrodes is a distance between the center lines of the electrodes in the extending direction (the centers of the electrodes in the width direction).

The interval of finger electrodes 9 on the light-receiving-side and the interval of finger electrodes 17 on the back-side may be equal to or different from each other. The amount of light incident from the back-side is 10% of the amount of light incident from the light-receiving-side, and therefore the finger electrode on the back-side is less affected by the shadowing loss due to an increase in electrode area as compared to the light-receiving surface. Thus, it is preferable that the back-side finger electrode is designed with priority given to carrier collecting efficiency, and is formed more densely than the light-receiving-side finger electrode. For example, the light-receiving-side finger electrode interval may be set to about 1.5 to 5 times as large as the back-side finger electrode interval.

The thickness of the finger electrode is preferably 10 to 40 μm, more preferably 15 to 30 μm. When the thickness of the finger electrode is in the above-mentioned range, line resistance can be reduced, and also utilization efficiency of electrode materials and simplicity of an electrode shape can be secured. When the thickness of the finger electrode is about 20 to 50% of the width of the finger electrode, an electrical loss caused by the shadowing loss and line resistance can be reduced.

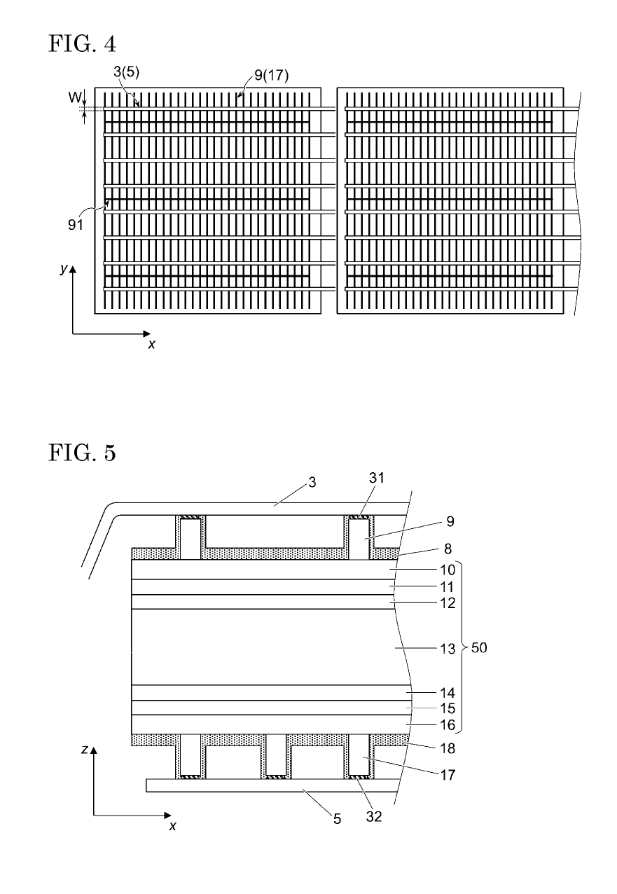

FIG. 4 is a plan view of a solar cell (solar cell string) after connection of the interconnector, where the interconnector 3 is disposed on the finger electrode 9. The extending direction of the interconnector (x direction) and the extending direction of the finger electrode (y direction) are orthogonal to each other. In this interconnection system, the finger electrode and the interconnector are connected at many points, and therefore it is not necessary to form a wide bus bar electrode orthogonally crossing the finger electrode. In the embodiment shown in FIG. 4, a compensation electrode 91 having a width substantially equal to that of the finger electrode is disposed so as to extend along a direction orthogonal to the finger electrode 9.

In connection of the finger electrode and the wire-shaped interconnector, the contact area at a contact part is smaller as compared to connection of a bus bar and a strip-shaped tab line, and therefore a contact failure between the electrode and the interconnector may occur. Preferably, the compensation electrode 91 that connects finger electrodes is provided to form a grid shape electrode pattern as shown in FIGS. 3B and 3C for reducing an electrical loss caused by a contact failure between the finger electrode and the interconnector. Even if a contact failure occurs at some of connection parts, photo induced carriers can be recovered to the interconnector from the finger electrode electrically connected through the adjacent compensation electrode, and therefore an electrical loss can be suppressed by providing the compensation electrode.

Preferably, the compensation electrode 91 is provided so as to extend along a direction orthogonal to the finger electrode, i.e., a direction parallel to the interconnector. In the solar cell module after interconnection, the compensation electrode may be disposed just under the interconnector 3, or disposed away from the interconnector. Preferably, the compensation electrode is positioned near the interconnector 3 in view of its role. The compensation electrode is not required to be disposed under all interconnectors 3, and for example, the compensation electrode may be disposed under some of the interconnectors. The number and arrangement interval of compensation electrodes may be different from the number and arrangement interval of interconnectors. The width of the compensation electrode may be equal to or different from the width of the finger electrode, and is preferably 15 to 120 μm, more preferably 50 to 100 μm.

When the compensation electrode is disposed just under the interconnector, stress may be concentrated if the electrode and the interconnector completely overlaps each other. Stress can be dispersed by providing the compensation electrode in a small angle zigzag form as shown in FIG. 3C.

The compensation electrode can be formed by printing of an electroconductive paste, a plating method or the like as in the case of the finger electrode. When the compensation electrode is formed by printing or plating, it is preferable that the finger electrode and the compensation electrode are formed at the same time. The finger electrode and the compensation electrode can be formed at the same time by, for example, performing printing using a screen mask having an opening pattern corresponding to the pattern shape of the finger electrode and the compensation electrode. In the plating method, the finger electrode and the compensation electrode can be formed at the same time by, for example, providing a resist with an opening corresponding to the pattern shape of the finger electrode and the compensation electrode, and performing plating.

(Insulating Layer)

The insulating layer 8 is disposed on at least one surface of the photoelectric conversion section. Preferably, the first insulating layer 8 and the second insulating layer 18 are disposed on the first principal surface and the second principal surface of the photoelectric conversion section, respectively. The insulating layers 8 and 18 are disposed so as to cover not only surfaces of the photoelectric conversion section 50 (transparent electrode layers 10 and 16) but also the finger electrodes 9 and 17, respectively, before connection to the interconnector. In the case where the compensation electrode orthogonally crossing the finger electrode is formed on a surface of the photoelectric conversion section, the insulating layer is disposed so as to also cover the compensation electrode. In other words, it is preferable that the insulating layers 8 and 18 are disposed so as to entirely cover both principal surfaces of the solar cell before connection to the interconnector. Regions in which the insulating layer is not formed may locally exist, such as pinholes that are inevitably generated during deposition of the insulating layer, fine cracks caused by thermal expansion, and contact portions with a tool for holding the substrate during deposition. Since not only the transparent electrode layer on a surface of the photoelectric conversion section but also the metal electrode is covered with the insulating layer, ingress of an alkali, moisture and so on into the photoelectric conversion section can be suppressed to improve the reliability of the solar cell.

It suffices that the insulating layers 8 and 18 have barrier property against an alkali and moisture, and examples of the material thereof include ceramic materials such as silicon oxide, silicon nitride, silicon oxynitride, aluminum oxide and molybdenum oxide, resin materials such as acryl-based resins and fluorine-based resins, and laminates thereof. Among them, silicon oxide, silicon nitride, silicon oxynitride, aluminum oxide, acryl-based resins and laminates thereof are preferably used from the viewpoint of a cost and a light transmittance. When the insulating layer is disposed on each of both surfaces of the photoelectric conversion section, the materials of the insulating layers on the front and back sides may be the same or different. The materials of the insulating layers on the front and back sides are preferably the same from the viewpoint of productivity.

The thickness of each of the insulating layers 8 and 18 is preferably 10 nm or more for imparting barrier property against an alkali, moisture and so on. In connection of the finger electrode and the interconnector, the insulating layer on the finger electrode is provided with an opening section, and the finger electrode and the interconnector are electrically connected through the opening section as described in detail later. The thickness of each of the insulating layers 8 and 18 is preferably 1000 nm or less for facilitating formation of the opening section. The thickness of each of the insulating layers 8 and 18 is more preferably 20 nm to 500 nm, further preferably 30 nm to 300 nm for both impartment of barrier property and facilitation of formation of the opening section.

The method for forming the insulating layers 8 and 18 is not particularly limited as long as the surfaces of the photoelectric conversion section and the finger electrode can be entirely covered, and any one of dry processes such as CVD and PVD and various kinds of wet processes may be selected according to the material of the insulating layer. It is preferable to form the insulating layer by a dry process because a thin-film having the above-mentioned thickness can be easily formed. When the photoelectric conversion section includes a silicon thin-film and a transparent electrode layer as in a heterojunction solar cell, it is preferable to perform deposition at 200° C. or lower for suppressing degradation of such a thin-film.

[Solar Cell Module]

FIG. 5 is a schematic sectional view of a solar cell (solar cell string) after connection of the interconnectors 3 and 5 to the finger electrodes 9 and 17, respectively. Opening sections are formed in the insulating layers 8 and 18 at parts on the finger electrodes 9 and 17 which cross the interconnectors 3 and 5, respectively. The opening sections of the insulating layers are filled with metallic materials 31 and 32, and the finger electrodes 9 and 17 are electrically connected, respectively, to the interconnectors 3 and 5 through the opening sections of the insulating layers.

(Interconnector)

As shown in FIG. 4, the interconnector is arranged orthogonal to finger electrodes and is arranged extending across a plurality of finger electrodes for electrically connecting them. It is preferable to use a thin metal wire as the interconnector, and a plurality of metal wires that are bound together may be used.

The width W of each of the interconnectors 3 and 5 along the in-plane direction of the principal surface of the photoelectric conversion section 50 (width in front view of the solar cell module from the light-receiving surface or back surface) is 50 μm or more and less than 400 μm. When the width W is less than 400 μm, shadowing loss can be reduced, and the opening is easily formed in the insulating layer during interconnection. When the width of the interconnector is 50 μm or more, an electrical loss caused by disconnection or line resistance can be suppressed. The width W of the interconnector is preferably 100 to 350 μm, more preferably 120 to 300 μm. In the solar cell module, the arrangement interval between adjacent interconnectors is preferably about 3 to 25 mm, more preferably 4 to 20 mm.

The cross-sectional shape of the interconnector is not particularly limited, and is, for example, a polygon such as a triangle, a tetragon or a pentagon, or a circle. An interconnector having a circular cross-sectional shape is preferably used because the interconnector is easily prepared. In addition, an interconnector having a circular cross-sectional shape has an advantage of ease of connection, since the cross-sectional shape has no anisotropy (specific direction) and thus it is not necessary to examine or adjust the direction of the interconnector during connection of the interconnector to the finger electrode. As described later, an interconnector having anisotropy in the cross-sectional shape may contribute to enhancing light utilization efficiency of the solar cell module.

Preferably, the material of the interconnector has a low resistivity for reducing a current loss caused by resistance. In particular, a metallic material mainly composed of copper is especially preferable because it is inexpensive. An interconnector may be used in which a surface of a core material composed of a metal such as copper is covered with a low-melting-point metallic material, or a high-reflectance metallic material such as Ag, Au or Al.

The surface covering layer of the interconnector may be provided over the whole of the core material, or provided partially on the core material. For example, a low-melting-point metallic material layer may be position-selectively provided in a period matching the arrangement interval of finger electrodes. When the cross-section of the interconnector has a non-circular shape, and aspect orientation control is performed as described later, a low-melting-point metallic material layer may be selectively provided on a surface that is in contact with the finger electrode. When a low-melting-point metallic material layer is position-selectively provided at a connection part between the interconnector and the finger electrode as described above, it is possible to reduce a material cost and an interconnection failure. Examples of the low-melting-point metallic material include metals such as In, Ga, Sn, Ga and Bi, and alloys (e.g., solder alloys) including any of these metals. The melting point of the low-melting-point metallic material is preferably 230° C. or lower, more preferably 200° C. or lower, further preferably 180° C. or lower.

(Arrangement of Interconnectors on Finger Electrode)

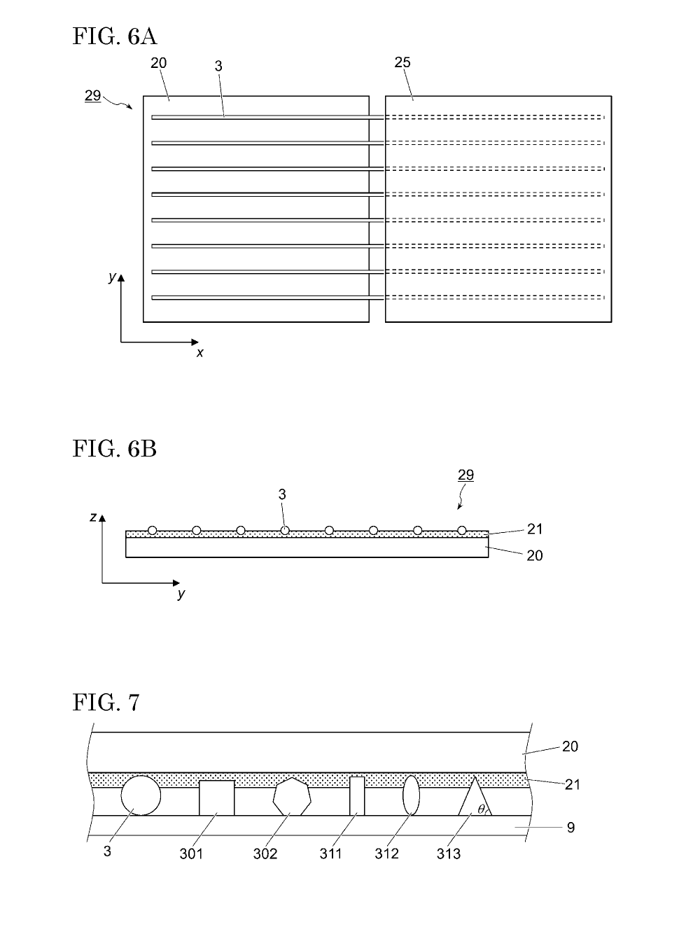

As described above, a plurality of interconnectors are arranged at a predetermined interval on the insulating layer so as to orthogonally cross the finger electrode. For appropriately arranging a plurality of interconnectors, it is necessary to adjust the position and the interval. By using a wiring-equipped base 29 in which the interconnectors 3 are arranged and attached on a support base 20 such as an insulating resin film beforehand as shown in FIGS. 6A and B, operations such as alignment can be simplified to improve productivity of the module.

FIG. 6A is a schematic plan view showing one embodiment of a wiring-equipped base in which a plurality of interconnectors 3 are attached on a support base, and FIG. 6B is a sectional view of the wiring-equipped base. When the wiring-equipped base 29 is arranged on a solar cell having an insulating layer, a plurality of interconnectors can be aligned in one-time.

In the embodiment shown in FIG. 6A the interconnectors 3 are bonded to a first principal surface of the first support base 20, and the interconnectors 3 are bonded to a second principal surface of a second support base 25. For example, when the first support base is arranged on the light-receiving-side of one solar cell, the second support base is arranged on the back-side of an adjacent solar cell, and an interconnector-equipped surface of each of the support bases and an insulating layer on a surface of the photoelectric conversion section are made to face each other, a plurality of interconnectors can be appropriately arranged on finger electrodes on the front and back sides of two solar cells.

The thickness and the material of the support base are not particularly limited. When the support base is removed after arrangement of interconnectors on a surface of the solar cell and before encapsulation, the support base may be transparent or opaque. When arrangement is examined or adjusted with using an optical detector such as a camera, a transparent support base is preferably used. When the module is encapsulated with the interconnector attached on the support base, a transparent support base is used.

As a material of the transparent support base, a transparent resin having heat resistance and UV resistance, such as a PET resin, a silicone resin, an acrylic resin, an epoxy resin or a fluorine-based resin, is preferable. An adhesive layer 21 may be provided on a surface of the support base as shown in FIG. 6B. The material and the thickness of the adhesive layer 21 are not particularly limited as long as the interconnector can be bonded and fixed to a surface of the layer. The thickness of the adhesive layer is, for example, about 2 to 10 μm, and the material of the adhesive layer is preferably a transparent resin. The support base itself may have adhesiveness.

When the adhesive layer 21 is provided on a surface of the support base, a support transparent resin adhesive layer is softened and laterally squeezed out from the contact point with the interconnector. Since the transparent resin adhesive that is squeezed out is bonded to the insulating layer on a surface of the photoelectric conversion section, the interconnector can be more firmly fixed.

As described above, the cross-sectional shape of the interconnector is non-anisotropic. Specifically, the aspect ratio of the lateral dimension (plane direction of the solar cell) and the longitudinal dimension (thickness direction) of the cross-section of the interconnector is preferably less than 1.5. When the cross-section of the interconnector has a large aspect ratio, a state in which the longer direction is parallel to the plane direction of the solar cell is dynamically stable, the width W of the interconnector tends to increase, leading to an increase in optical loss due to reflection.

When a mechanism for controlling the orientation of the cross-section aspect ratio of the interconnector (hereinafter, referred to as cross-section aspect orientation control) is provided, the cross-section of the interconnector may have a large aspect ratio. In this case, it is preferable that interconnectors are arranged in such a manner that the cross-section of the interconnector has a length larger along the normal direction of the substrate than along the in-plane direction of the substrate, i.e., the cross-section of the interconnector has a high aspect ratio along the normal direction of the principal surface of the substrate 13.

FIG. 7 is a conceptual view showing a state in which interconnectors having various cross-sectional shapes are arranged on the finger electrode 9 of the solar cell by cross-section aspect orientation control. FIG. 7 shows an example in which cross-section aspect orientation control is performed by bonding the interconnector to the support base 20 provided with the adhesive layer 21. In FIG. 7, the illustration of the insulating layer is omitted.

The interconnectors 3 having a circular cross-sectional shape have an aspect ratio of 1, and are arranged on the finger electrode constantly in the same direction regardless of whether cross-section aspect orientation control is performed or not. Interconnectors 301 having a square cross-sectional shape and interconnectors 302 having a regular-polygonal cross-sectional shape have an aspect ratio of 1, and are arranged on the finger electrode in the same direction regardless of whether cross-section aspect orientation control is performed or not. In view of dynamic stability, the interconnectors 301 and 302 are often arranged in such a manner that any of the sides of the interconnector is parallel to the substrate surface.

Like interconnectors 311 having an oblong cross-sectional shape and interconnectors 312 having an elliptic cross-sectional shape, interconnectors having a large aspect ratio tend to be arranged in such a manner that the longer side (major axis) is parallel to the substrate surface in view of dynamic stability when cross-section orientation control is not performed. In this case, the width on the substrate surface increases, resulting in a large optical loss caused by light reflection at the interconnector, and thus the light utilization efficiency of the solar cell module is deteriorated. On the other hand, when cross-section aspect orientation control is performed, and interconnectors are arranged in such a manner that the longer side (major axis) is parallel to the normal line of the substrate surface as shown in FIG. 7, the width on the substrate surface decreases. In this case, the interconnector has a larger cross-sectional area as compared to an interconnector having a smaller aspect ratio and having the same width, and therefore the line resistance of the interconnector tends to decrease, leading to improvement of module characteristics. Thus, when interconnectors having a large aspect ratio (for example, 1.5 or more) are used, and cross-section aspect orientation control is performed, module characteristics can be improved.

When cross-section aspect orientation control is performed so as to increase the inclination angle θ in the case of an interconnector having an inclined surface like the interconnector 313, light reflected at the interconnector is totally reflected when reflected at the interface between the protecting member 1 and air, and therefore emission of incident light to outside the module can be prevented to improve the light utilization efficiency of the module. For example, when the protecting member 1 is glass (refractive index: 1.5), light reflected at the interconnector 313 is totally reflected at the interface between the protecting member 1 and air when the inclination angle θ is 41° or more.

Cross-section aspect orientation control of the interconnector can be performed by a method other than using a support base. For example, when interconnectors are embedded and fixed in the encapsulants 2 and 6, the orientation of interconnectors can be controlled without using a support base. The orientation of interconnectors may be controlled by performing interconnection with aspect orientation control performed by, for example, a method in which a part of the interconnector which is not in contact with the finger electrode is held by a support tool.

(Formation of Opening Section)

Interconnectors are arranged so as to orthogonally cross finger electrodes, and an opening section is locally formed in each of the insulating layers 8 and 18 between the interconnectors 3 and 5 and the finger electrodes 9 and 17, respectively, to electrically connect the interconnectors to the finger electrodes. The electrical connection is performed by, for example, a method in which the interconnector and the finger electrode are brought into physical contact with each other under the pressure of the encapsulant, etc., or a method in which the opening section between the interconnector and the finger electrode is filled with metallic materials 31 and 32.

Formation of the opening section in the insulating layer is performed by a method capable of locally forming an opening section at a connection part between the finger electrode and the interconnector. The opening section is locally formed in the insulating layer on the finger electrode by, for example, applying a pressure with the interconnector arranged on the finger electrode. Local heating in solder connection, thermocompression bonding or the like thermally expands the finger electrode to form a crack-like opening section in the insulating layer on the finger electrode.

When the opening section is provided by limiting a deposition region using a mask etc. during deposition of the insulating layer, alignment of the mask is necessary. It is necessary that a covering region with the mask be made large for providing a margin in alignment, and therefore the opening section is formed in a region larger than the interconnection region. Thus, the photoelectric conversion section and the electrode tend to have exposed parts, leading to deterioration of reliability of the solar cell module.

On the other hand, in the present invention, the insulating layers 8 and 18 are formed so as to cover the whole surface of each of the photoelectric conversion section and the electrode, and the opening section is then locally formed at parts (interconnection parts) where the interconnectors 3 and 5 are in contact with and bonded to the finger electrodes 9 and 17. This method is preferable from the viewpoint of productivity because formation of the opening section can be automatically concentrated on the interconnection part that requires the opening section. The opening section is locally formed at the interconnection part, and the opening section is infilled by connection of the electrode and the interconnector. Thus, the whole surface of each of the photoelectric conversion section and the electrode is covered with the insulating layer or the interconnector, and thus exposed parts hardly exist, so that the reliability of the solar cell module can be improved.

A tab line that is commonly used as an interconnector has a width of about 0.8 to 2 mm, and the contact cross-sectional area between the electrode (bus bar electrode) of the solar cell and the tab line is large. Thus, it is difficult to form the opening section in the insulating layer by locally applying a pressure to the interconnection part. On the other hand, the opening section can be easily formed by using an interconnector having a width of less than 400 μm, because a pressure is easily locally applied to the contact part with the insulating layer on the finger electrode.

(Connection of Interconnector)

Preferably, the opening section formed in the insulating layers 8 and 18 are filled with the metallic materials 31 and 32 to electrically connect the interconnectors 3 and 5 to the finger electrodes 9 and 17, respectively, for improving connection reliability. Examples of the method for filling the opening section with the metallic material include application of an electroconductive paste, connection by molten solder, welding by a low-melting-point metal such as In, and deposition of a metal by plating. It is preferable from the viewpoint of productivity that the interconnector is brought into contact with the interconnection part to form the opening section in the insulating layer, and the opening section is filled with the metallic material by heating and melting or plating of a metal while the contact state of the interconnector is maintained.

The opening section can be filled with the metallic material by, for example, heat-melting a covering metal layer disposed on the surface of the interconnector. In this case, the opening section of the insulating layer is filled with a metallic material that forms the covering metal layer of the interconnector, or an alloy material of a metallic material that forms the covering metal layer and a metallic material that forms the finger electrode. For example, when an interconnector covered with solder is used, the interconnection part is locally heated to melt the solder, and the opening section is filled with the molten solder, whereby the finger electrode and the interconnector can be welded to each other. When an interconnector covered with a metallic material such as In is used, the covering metallic material may be melted by thermocompression bonding to weld the finger electrode and the interconnector to each other. In these methods, formation of a crack-like opening section in the insulating layer by thermal expansion of the finger electrode by heating and filling of the molten metallic material into the opening section may substantially simultaneously proceed. When the metallic material that forms the finger electrode is melted in melting of the covering metal layer of the interconnector, an alloy of the covering metallic material of the interconnector and the metallic material that forms the finger electrode may be formed. Particularly, a solder material has high compatibility with copper, and therefore when the interconnector is solder-connected onto a copper electrode, an alloy is easily formed in the opening section of the insulating layer.

When the finger electrode is fed with electricity to perform electroplating while the interconnector is in contact with the interconnection part, a plated metal is locally deposited near the opening section of the insulating layer disposed on the finger electrode. By the plated metal, the finger electrode under the opening section and the interconnector disposed thereon can be brought into conduction with each other to establish electrical connection between the finger electrode and the interconnector. Fine openings (cracks) may be generated in the insulating layer on the finger electrode due to a change in volume of the metallic material during baking of the electroconductive paste (see, for example, WO 2013/077038). When interconnection is performed by electroplating, a plated metal may be deposited on the finger electrode in regions other than the interconnection region through the fine openings of the insulating layers 8 and 18, such a level of fine cracks and deposited metal do not significantly affect the conversion characteristics and reliability of the module.

(Encapsulation)

A solar cell string with a plurality of solar cells connected through interconnectors are encapsulated with an encapsulant to obtain a solar cell module. For example, the encapsulants 2 and 6 and the protecting members 1 and 7 are arranged and stacked on the light-receiving-side and the back-side, respectively, of the solar cell string, and heated and press-bonded, whereby the encapsulants flow into the gap between adjacent solar cells and the ends of the module to perform modularization.

As the encapsulant 2 and 6, a transparent resin such as an ethylene/vinyl acetate copolymer (EVA), ethylene/vinyl acetate/triallyl isocyanurate (EVAT), polyvinyl butyrate (PVB), silicon, urethane, acryl or epoxy is preferably used.

Preferably, a space surrounded by two adjacent finger electrodes 9, the interconnector 3 connecting these finger electrodes 9, and the insulating layer 8 disposed on a surface of the photoelectric conversion section are also filled with the encapsulant. Accordingly, a difference in refractive index between the solar cell string and the surroundings is eliminated, so that light is diffused to the filled space, and therefore the optical confinement effect is improved. The encapsulant 2 forms an adhesion state between the insulating layer 8 and the interconnector 3, and therefore the interconnector 3 is more firmly connected to the solar cell 4, so that the reliability of the module is improved.

The light-receiving-side protecting member 1 is transparent, and examples of the material thereof include a glass substrates (blue glass plate or white glass plate), and organic films including fluororesin film such as a polyvinyl fluoride film (for example, a TEDLAR film (registered trademark), and a polyethylene terephthalate (PET) film. From the viewpoint of mechanical strength, optical transmittance, water blocking performance, costs and others, a glass plate is preferred and a white glass plate is particularly preferred.

The back-side protecting member 7 may be either of transparent, light-absorbing or light-reflecting. As a transparent protecting member, materials previously mentioned for the light-receiving-side protecting member are preferably used. As a light-reflecting back-side protecting member, one having a metallic color or white color is preferable, and a white resin film, a laminate with a metal foil of aluminum etc. sandwiched between resin films, or the like is preferably used. As a light-absorbing protecting material, one including a black resin layer, for example, is used.

### EXAMPLE

Hereinafter, the present invention will be described in detail by showing examples, but the present invention is not limited to the following examples.

[Preparation of Photoelectric Conversion Section of Heterojunction Solar Cell]

A 6-inch n-type single-crystalline silicon substrate having a light-incident-surface with a (100) plane orientation and having a thickness of 200 μm was washed in acetone, immersed in a 2 wt % HF aqueous solution for 5 minutes to remove a silicon oxide layer on a surface, and rinsed twice with ultra-pure water. Washed silicon substrate was immersed for 15 minutes in a 5/15 wt % KOH/isopropyl alcohol aqueous solution held at 75° C. Thereafter, the substrate was immersed in a 2 wt % HF aqueous solution for 5 minutes, rinsed twice with ultra-pure water, and then dried at ambient temperature. Surfaces of the single-crystalline silicon substrate were observed with an atomic force microscope (AFM) to confirm that quadrangular pyramid-like textured structures on both surfaces. The arithmetic mean roughness of the texture was 2100 nm.

The surface of the single-crystalline silicon substrate after formation of textures was immersed in a 5% HCl aqueous solution at 70° C. for 5 minutes to neutralize an alkali component remaining on the surface. Thereafter, the surface was cleaned for 10 minutes using 15 ppm of ozone water, and immersed in a 5% HF aqueous solution for 2 minutes to remove an ozone-oxidized film.

The substrate was introduced into a CVD apparatus. On one surface of the substrate, an i-type amorphous silicon layer as a light-receiving-side intrinsic silicon layer was deposited to have a thickness of 4 nm, and thereon a p-type amorphous silicon layer as a light-receiving-side conductive silicon layer was deposited to have a thickness of 5 nm. Deposition conditions of the i-type amorphous silicon layers included a substrate temperature of 180° C., a pressure of 130 Pa, a SiH₄/H₂ flow ratio of 2/10 and a supplied power density of 0.03 W/cm². Deposition conditions of the p-type amorphous silicon layer included a substrate temperature of 190° C., a pressure of 130 Pa, an SiH₄/H₂/B₂H₆ flow ratio of 1/10/3 and a supplied power density of 0.04 W/cm². With respect to the B₂H₆ gas mentioned above, a diluting gas wherein B₂H₆ was diluted with H₂ gas to have a concentration of 5000 ppm was used.

Thereafter, on the other surface of the substrate, an i-type amorphous silicon layer as a back-side intrinsic silicon layer was deposited to have a thickness of 5 nm, and thereon an n-type amorphous silicon layer as a back-side conductive silicon layer was deposited to have a thickness of 10 nm. Deposition conditions of the n-type amorphous silicon layer included a substrate temperature of 180° C., a pressure of 60 Pa, an SiH₄/PH₃ flow ratio of ½ and a supplied power density of 0.02 W/cm². With respect to the PH₃ gas mentioned above, a diluting gas wherein PH₃ was diluted with H₂ gas to have a concentration of 5000 ppm was used.

The substrate was transferred to a sputtering chamber, and on the p-type amorphous silicon layer, an ITO layer was formed as a light-receiving-side transparent electrode in a thickness of 120 nm. Thereafter, on the n-type amorphous silicon layer, an ITO layer was formed as a back-side transparent electrode in a thickness of 100 nm. In deposition of each of the ITO layers, a sputtering target obtained by adding 10% by weight of SnO₂ to In₂O₃ was used.

In the following Examples and Comparative Examples, a solar cell was prepared by forming an electrode on a transparent electrode layer of the photoelectric conversion section (solar cell-in-process) obtained as described above, and a plurality of solar cells were connected through an interconnector to modularize the solar cells.

### Example 1

(Formation of Grid Electrode)

A light-receiving-side grid electrode including finger electrodes and compensation electrodes orthogonally crossing the finger electrodes (electrodes extending across the finger electrodes) was formed on a transparent electrode layer on a light-receiving surface by screen printing of a silver paste. The interval between adjacent finger electrodes was 2 mm, and the interval between compensation electrodes was 30 mm. The width of the compensation electrode was substantially equal to the width of the finger electrode, and a wide bus bar electrode was not provided.

A grid electrode including finger electrodes and compensation electrodes was formed on a back-side transparent electrode layer as in the case of the light-receiving side. The number of compensation electrodes on the back-side grid electrode was equal to the number of compensation electrodes on the light-receiving-side grid electrode, and the number of finger electrodes on the back-side grid electrode was about two times as many as the number of finger electrodes on the light-receiving-side.

(Formation of Insulating Layer)

The solar cell after formation of the metal electrode was introduced into a CVD device to deposit a 100 nm-thick silicon oxide layer as an insulating layer on each of the light-receiving surface and the back surface by a plasma-enhanced CVD method.

(Interconnection)

A metal wire with a diameter of about 180 μm in which the surface of a copper wire with a diameter of 170 μm was coated with an indium layer with a thickness of 5 μm was used as an interconnector. The interconnectors were arranged at intervals of 6 mm so as to orthogonally cross the finger electrodes of the solar cell, the light-receiving-side finger electrodes and the back-side finger electrodes of two adjacent solar cells were connected by the interconnectors, and a solar cell string with nine solar cells connected in series was formed.

A part where the interconnector was superposed on the finger electrode was thermocompression-bonded at 180° C. for 2 minutes to weld indium on the surface of the interconnector to the Ag finger electrode, thereby connecting the finger electrode and the interconnector. The transparent electrode layer and the grid electrode on both surfaces were covered with the insulating layer. On a part where the interconnector and the finger electrode are welded, an opening section passing through the insulating layer was formed. The opening section was formed by cracks generated in the insulating layer due to deformation of the finger electrode by contact between the finger electrode and the interconnector.

(Encapsulation)

Six solar cell strings (54 solar cells in total) were connected in series to prepare a string assembly. A 4 mm-thick white glass plate as a light-receiving-side protecting member, a 400 μm-thick EVA sheet as each of a light-receiving-side encapsulant and a back-side encapsulant, and a PET film as a back sheet were provided, the string assembly was sandwiched between the two EVA sheets, and laminated at 150° C. for 20 minutes to obtain a solar cell module.

### Example 2

Interconnectors each having an uncovered surface and a diameter of 170 μm were connected to the finger electrodes by electroplating. Except the interconnection, the same procedure as in Example 1 was carried out to prepare a solar cell module.

The interconnector was brought into contact with the finger electrode to form an opening section in an insulating layer. Electrolytic copper plating was performed with the interconnector being in contact with the finger electrode, whereby plated-copper was deposited between the interconnector and the finger electrode exposed under the opening section. The contact point between the surface of the interconnector and the finger electrode was covered with 1-3 μm-thick plated copper, and satisfactory connection was established.

### Example 3

Except that the light-receiving-side grid electrode and the back-side grid electrode were formed by copper plating, the same procedure as in Example 1 was carried out to prepare a solar cell module.

A 100 nm-thick Ni layer and a 150 nm-thick Cu seed layer were formed on each of a light-receiving-side transparent electrode layer and a back-side transparent electrode layer by a sputtering method. A resist was applied onto the Cu seed layer on both of the front and back sides, and exposed and developed to form a resist opening with a shape matching a grid electrode pattern. By electrolytic copper plating, a plated copper electrode was formed on the Cu seed layer exposed under the resist opening, the resist was then removed, and the Ni layer/Cu seed layer remaining between plated copper electrodes was removed by etching. Thereafter, by a plasma-enhanced CVD method, a 100 nm-thick silicon oxide layer was deposited so as to cover the photoelectric conversion section and the plated copper electrode.

### Example 4

In formation of an insulating layer, a 100 nm-thick silicon oxide layer was deposited only on the light-receiving surface as the insulating layer, and the insulating layer was not formed on the back surface. Except this change, the same procedure as in Example 1 was carried out to prepare a solar cell module.

### Example 5

In formation of an insulating layer, a 100 nm-thick silicon oxide layer was deposited only on the back surface as the insulating layer, and the insulating layer was not formed on the light-receiving surface. Except this change, the same procedure as in Example 1 was carried out to prepare a solar cell module.

### Example 6

A light-receiving-side grid electrode and a back-side grid electrode were formed by copper plating in the same manner as in Example 3, and a copper wire having a diameter of 170 μm and covered with solder (thickness: 30 to 80 μm) was then solder-connected to a finger electrode in interconnection. In solder connection, the solder was melted by locally heating the contact point with the finger electrode being in contact with the interconnector, so that the interconnector was welded to the finger electrode.

### Example 7

A light-receiving-side grid electrode and a back-side grid electrode were formed by copper plating in the same manner as in Example 3, and a finger electrode and an interconnector were then connected by electroplating in the same manner as in Example 2.

### Example 8

In the same manner as in Example 1, a grid electrode was formed using a silver paste, and an insulating layer was formed, followed by storing a solar cell under an environment at a humidity of 60% and an air temperature of 27° C. for 10 days. Thereafter, interconnection and encapsulation were performed in the same manner as in Example 1 to obtain a solar cell module.

### Comparative Example 1

Except that an insulating layer was not formed on either of the light-receiving surface and the back surface of a photoelectric conversion section, the same procedure as in Example 1 was carried out to prepare a solar cell module.

### Comparative Example 2

In the same manner as in Example 1, a grid electrode was formed on each of the light-receiving surface and the back surface using a silver paste. The interval between finger electrodes was equal to the interval between finger electrodes in Example 1. Along a direction orthogonally crossing the finger electrode, four bus bar electrodes each having a width of 1.5 mm were disposed in place of compensation electrodes as electrodes extending across the finger electrodes. These bus bar electrodes were arranged in such a manner that the interval (center-to-center distance) between adjacent electrodes was 39 mm. After formation of the electrodes, an insulating layer was not formed, and interconnection was performed.

A strip-shaped tab line having a width of 1.5 mm and a thickness of 250 μm (a copper foil with a surface covered with 5-7 μm-thick solder) was used as an interconnector. The tab line was arranged so as to overlap the bus bar, and solder connection was performed.

### Comparative Example 3

In the same manner as in Comparative Example 2, a grid electrode including finger electrodes and bus bar electrodes was formed on each of the light-receiving surface and the back surface using a silver paste. Thereafter, and a 100 nm-thick silicon oxide layer as an insulating layer was deposited on only a transparent electrode layer and the finger electrodes, while the bus bar electrodes as interconnection region were covered with a mask. Thus, the insulating layer was not formed in the interconnection region. After formation of the insulating layer, a tab line on the bus bar was solder-connected to perform interconnection in the same manner as in Comparative Example 2.

### Comparative Example 4

A tab line on the bus bar was solder-connected to perform interconnection in the same manner as in Comparative Example 3 except that in formation of an insulating layer, a mask was not used, and the insulating layer was deposited on the whole surface of each of a transparent electrode layer and a grid electrode.

### Comparative Example 5

In formation of an insulating layer, the insulating layer was deposited while the finger electrodes and compensation electrodes are covered with a mask, so that a 100 nm-thick silicon oxide layer was deposited on only a transparent electrode layer. Except this change, the same procedure as in Example 1 was carried out to prepare a solar cell module.

### Comparative Example 6

In formation of an insulating layer, the insulating layer was deposited while interconnection regions on finger electrodes are covered with a mask, so that a 100 nm-thick silicon oxide layer was deposited in regions other than the interconnection regions a transparent electrode layer, a compensation electrode, and a part of the finger electrode which is not in contact with the metal wire). Except this change, the same procedure as in Example 1 was carried out to prepare a solar cell module.

### Comparative Example 7

An attempt was made to connect an interconnector onto a copper-plated grid electrode in the same manner as in Example 6 without forming an insulating layer on either of the light-receiving surface and the back surface of a photoelectric conversion section. However, it was unable to appropriately solder-bond the interconnector (solder-covered copper wire) onto the copper-plated grid electrode, so that adhesion of the interconnector was insufficient, and therefore appropriate interconnection was not performed.

### Comparative Example 8

In formation of an insulating layer, deposition was performed while interconnection regions on finger electrodes were covered with a mask, so that a 100 nm-thick silicon oxide layer was deposited in regions other than the interconnection regions. An attempt was made to connect the interconnector onto a copper-plated grid electrode in the same manner as in Example 6 except for the above, but interconnection was not established.

### Comparative Example 9

Except that an insulating layer was not formed on either of the light-receiving surface and the back surface of a photoelectric conversion section, the same procedure as in Example 1 was carried out to prepare a solar cell module.

### Comparative Example 10

In the same manner as in Example 1, a grid electrode was formed using a silver paste, and a solar cell without having an insulating layer was then stored under an environment at a humidity of 60% and an air temperature of 27° C. for 10 days. Thereafter, no insulating layer was formed, and interconnection and encapsulation were performed in the same manner as in Example 1 to obtain a solar cell module.

[Evaluation]

The power generation characteristics of the solar cell module in each of Examples and Comparative Examples (except for Comparative Examples 7 and 8) were measured, and the solar cell module was then stored in a thermostatic bath at a temperature of 85° C. and a humidity of 85% for 2000 hours. The power generation characteristics of the solar cell module taken out from the thermostatic bath after a heat resistance and moisture resistance reliability test were measured, and the ratio of powers before and after the reliability test was defined as a retention ratio. The configurations of grid electrodes (materials and kinds of transverse electrodes orthogonally crossing finger electrodes), the forms of insulating layers (formation surfaces, and presence/absence of insulating layers on grid electrodes and interconnection (IC) regions on formation surfaces), the materials of interconnectors and the interconnection methods, and the power generation characteristics in solar cell modules in Examples and Comparative Examples are shown in Table 1.

TABLE 1

| | | | | | | | | | Powder | |
|---|---|---|---|---|---|---|---|---|---|---|
| | | | | | | | | | after | |
| | Grid electrode | | Insulating layer | | | | | Initial | reliability | Reten- |
| | | Transverse | Formation | On grid | IC | Interconnection | | powder | test | tion |
| | Material | electrode | surface | electrode | region | Material | Method | (W) | (W) | ratio |
| Example 1 | Ag paste | Compensation | Both surfaces | Present | Present | In-coated wire | Thermocompression | 275.4 | 272.0 | 98.77% |
| | | electrode | | | | | bonding | | | |
| Example 2 | Ag paste | Compensation | Both surfaces | Present | Present | Cu metal wire | Plating | 278.1 | 274.5 | 98.72% |
| | | electrode | | | | | | | | |
| Example 3 | Cu plating | Compensation | Both surfaces | Present | Present | In-coated wire | Thermocompression | 286.2 | 281.2 | 98.25% |
| | | electrode | | | | | bonding | | | |
| Example 4 | Ag paste | Compensation | Light-receiving | Present | Present | In-coated wire | Thermocompression | 275.0 | 268.6 | 97.68% |
| | | electrode | surface | | | | bonding | | | |
| Example 5 | Ag paste | Compensation | Back surface | Present | Present | In-coated wire | Thermocompression | 275.1 | 267.4 | 97.21% |
| | | electrode | | | | | bonding | | | |
| Example 6 | Cu plating | Compensation | Both surfaces | Present | Present | Solder-coated | Solder welding | 285.5 | 281.3 | 98.53% |
| | | electrode | | | | wire | | | | |
| Example 7 | Cu plating | Compensation | Both surfaces | Present | Present | Cu metal wire | Plating | 288.5 | 283.4 | 98.23% |
| | | electrode | | | | | | | | |
| Comparative | Ag paste | Compensation | — | | | In-coated wire | Thermocompression | 274.9 | 249.2 | 90.65% |
| Example 1 | | electrode | | | | | bonding | | | |
| Comparative | Ag paste | Bus bar | — | | | Tub line | Solder welding | 272.0 | 251.2 | 92.35% |
| Example 2 | | | | | | | | | | |
| Comparative | Ag paste | Bus bar | Both surfaces | Present | Absent | Tub line | Solder welding | 271.9 | 257.1 | 94.55% |
| Example 3 | | | | | | | | | | |
| Comparative | Ag paste | Bus bar | Both surfaces | Present | Present | Tub line | Solder welding | 258.8 | 254.9 | 98.51% |
| Example 4 | | | | | | | | | | |
| Comparative | Ag paste | Compensation | Both surfaces | Absent | Absent | In-coated wire | Thermocompression | 274.9 | 264.6 | 96.25% |
| Example 5 | | electrode | | | | | bonding | | | |
| Comparative | Ag paste | Compensation | Both surfaces | Present | Absent | In-coated wire | Thermocompression | 275.3 | 265.9 | 96.57% |
| Example 6 | | electrode | | | | | bonding g | | | |
| Comparative | Cu plating | Compensation | | | | Solder-coated | Solder welding | — | | |
| Example 7 | | electrode | | | | wire | | | | |
| Comparative | Cu plating | Compensation | Both surfaces | Present | Absent | Solder-coated | Solder welding | — | | |
| Example 8 | | electrode | | | | wire | | | | |
| Comparative | Cu plating | Compensation | — | | | Cu metal wire | Plating | 231.1 | 189.7 | 82.10% |
| Example 9 | | electrode | | | | | | | | |
| Example 8 | Ag paste | Compensation | Both surfaces | Present | Present | In-coated wire | Thermocompression | 275.4 | 268.6 | 97.54% |
| | | electrode | | | | | bonding | | | |

| | | | | | | | | |
|---|---|---|---|---|---|---|---|---|
| Comparative | Ag paste | Compensation | — | In-coated wire | Thermocompression | 273.2 | 248.9 | 91.10% |
| Example 10 | | electrode | | | bonding | | | |

For the initial power of the module, Examples 1 to 7 and Comparative Examples 1 and 5 to 8 in which a copper thin wire was used as an interconnector showed a higher value as compared to Comparative Examples 2 to 4 in which a tab line was used. This is ascribable to an increase in electric current due to reduction of a shadowing loss by the electrode and improvement of a fill factor due to reduction of resistance of the interconnector. Among them, Examples 3, 6, and 7 in which a grid electrode was formed by copper plating showed a particularly high power. This is because as compared to a metal paste electrode containing a resin material, a plated electrode has a lower resistivity, resulting in a reduction in electrical loss caused by series resistance.

Comparison of Examples 1, 4, and 5 and Comparative Examples 1, 5, and 6 in which a copper wire with a surface coated with an In alloy was used as an interconnector shows that there was almost no difference in initial power, but for the retention ratio after the reliability test, Example 1 in which the insulating layer was formed over the whole of each of both surfaces showed a particularly high value, and Examples 4 and 5 in which the insulating layer was formed on one of the light-receiving surface and the back surface showed the next highest value. Comparative Example 1 in which the insulating layer was not disposed on either of the light-receiving surface and the back surface showed a considerably low retention ratio. In Comparative Examples 5 and 6, the insulating layer was disposed on both the surfaces, but Comparative Examples 5 and 6 showed a lower retention ratio as compared to Examples 4 and 5 in which the insulating layer was disposed on only one of the surfaces. From these results, it is apparent that a structure in which a boundary part between the transparent electrode and the grid electrode on a surface of the photoelectric conversion section is covered with the insulating layer in the interconnection region is effective for module reliability improvement.

Comparison of Example 6 and Comparative Examples 7 and 8 in which as the interconnector, a solder-coated metal wire was connected onto the copper-plated electrode shows that Example 6 showed an excellent initial power and an excellent retention ratio after the reliability test, whereas in Comparative Examples 7 and 8 in which the insulating layer was not disposed in the interconnection region, a connection failure between copper and solder occurred. Observation of the cross-section of the interconnection region in Comparative Examples 7 and 8 showed that copper in the plated electrode was melted with solder, and drawn toward the interconnector, so that voids were formed. This is because the alloying rate between copper and solder is high, resulting in occurrence of so called solder erosion.

In Example 6, flow of copper toward the solder is suppressed because the surface of the plated electrode is covered with the insulating layer in regions other than fine opening sections in the interconnection region. Thus, it is considered that the alloy forming part of flowing solder and copper is limited to the vicinity of the opening section of the insulating layer to suppress excessive alloying, so that satisfactory solder connection can be attained.

Example 8 in which a storage time period of 10 days was provided after preparation of the solar cell and before interconnection showed a high initial power and retention ratio similarly to Example 1 in which a storage time period was not provided. Comparative Example 10 in which the insulating layer was not provided showed a lower initial power and retention ratio as compared to Comparative Example 1 in which a storage time period was not provided. From these results, it is apparent that by covering the surfaces of the photoelectric conversion section and the metal electrode with the insulating layer, reliability after modularization is improved, and also deterioration of quality during a time period after preparation of the solar cell and before modularization can be suppressed.

### DESCRIPTION OF REFERENCE CHARACTERS

1, 7 protecting member

2, 6 encapsulant

3, 5 interconnector

4 crystalline silicon solar cell

50 photoelectric conversion section

13 crystalline silicon substrate

11, 15 conductive silicon layer

12, 14 intrinsic silicon layer

10, 16 transparent electrode layer

8, 18 insulating layer

9, 17 finger electrode

91 compensation electrode

1. A crystalline silicon solar cell module comprising:
a crystalline silicon solar cell; and
an interconnector electrically connected to the crystalline silicon solar cell, wherein
the crystalline silicon solar cell comprises:
a photoelectric conversion section having a first surface and a second surface opposite to the first surface;
a plurality of first finger electrodes arranged side by side on the first surface of the photoelectric conversion section; and
a first insulating layer over the first surface of the photoelectric conversion section and the first finger electrodes,
the interconnector extends across the plurality of first finger electrodes and electrically connects the first finger electrodes, and
the first insulating layer has an opening through which the first finger electrodes and the interconnector are electrically connected.

2. The crystalline silicon solar cell module according to claim 1, further comprising:
a metallic material in the opening that electrically connects the first finger electrode and the interconnector.

3. The crystalline silicon solar cell module according to claim 2, wherein
the interconnector further comprises a low-melting-point metallic material layer in contact with the first insulating layer, and
the metallic material in the opening comprises the low-melting-point metallic material layer, or an alloy of a metallic material comprising the low-melting-point metallic material and a metallic material comprising the first finger electrode.

4. The crystalline silicon solar cell module according to claim 2, wherein the metal material in the opening is a plated metal.

5. The crystalline silicon solar cell module according to claim 1,
the first finger electrode further comprises plated copper under the insulating layer.

6. The crystalline silicon solar cell module according to claim 1, wherein a cross-section of the interconnector has a length larger along a normal direction of the first surface of the photoelectric conversion section than along the in-plane direction of the first surface of the photoelectric conversion section.

7. The crystalline silicon solar cell module according to claim 1,
wherein
the photoelectric conversion section further comprises a first intrinsic silicon layer, a first conductive silicon layer and a first transparent electrode layer over a single-crystalline silicon substrate, and
the first finger electrode and the first insulating layer are over the first transparent electrode layer.

8. The crystalline silicon solar cell module according to claim 1, wherein
the crystalline silicon solar cell further comprises:
a plurality of second finger electrodes arranged side by side on the second surface of the photoelectric conversion section; and
a second insulating layer over the second surface of the photoelectric conversion section and the second finger electrodes,
the interconnector extends across the plurality of second finger electrodes and electrically connects the second finger electrodes, and
the second insulating layer has an opening through which the second finger electrodes and the interconnector are electrically connected.

9-12. (canceled)

13. The method according to claim 15, wherein communicatively coupling the first solar cell with the second solar cell further comprises:
attaching the interconnector and one or more other interconnectors to a support base to form a wiring-equipped base;
causing an interconnector-attached surface of the wiring-equipped base and the insulating layer of the first solar cell or the second solar cell to be in contact with each other to arrange the interconnectors on the insulating layer of the first solar cell or the second solar cell

14. The manufacturing method of a crystalline silicon solar cell module according to claim 15, the method further comprising:
arranging the interconnector on the insulating layer of the first solar cell or the second solar cell in such a manner that the interconnector has a length in a first direction along a surface of the photoelectric conversion section greater than a width in a second direction normal to the first direction along the surface of the photoelectric conversion section.

15. A method, comprising:
forming one or more of a first solar cell or a second solar cell, wherein forming the first solar cell or the second solar cell, comprises:
forming a photoelectric conversion section comprising a substrate and a transparent electrode layer over the substrate;
forming a plurality of finger electrodes over the photoelectric conversion section, the finger electrodes of the plurality of finger electrodes being formed side by side and extending in a first direction;
forming an insulating layer over the photoelectric conversion section and the finger electrodes of the plurality of finger electrodes;
communicatively coupling the first solar cell with the second solar cell by electrically connecting the finger electrodes of the first solar cell with an interconnector extending in a second direction different from the first direction, and electrically connecting the finger electrodes of the second solar cell with the interconnector,
wherein the interconnector is caused to be electrically connected with one or more of the finger electrodes of the first solar cell or the finger electrodes of the second solar cell through the insulation layer.

16. The method according to claim 15, wherein
the substrate comprises a first side and a second side opposite the first side,
the transparent electrode layer is a first transparent electrode layer over the first side of the substrate,
the finger electrodes are first finger electrodes over the first transparent layer,
forming one of more of the first solar cell or the second solar cell further comprises:
forming a second transparent electrode layer of the second side of the substrate;
forming a plurality of second finger electrodes over the second transparent electrode layer, the second finger electrodes of the plurality of second finger electrodes being formed side by side and extending in a third direction; and
forming a second insulating layer over the second transparent electrode layer and the second finger electrodes of plurality of second finger electrodes, and
communicatively coupling the first solar cell with the second solar cell comprises electrically connecting the first finger electrodes of the first solar cell with the interconnector and electrically connecting the second finger electrodes of the second solar cell with the interconnector.

17. The method according to claim 15, further comprising:
selectively forming a plurality openings in the insulating layer at positions where the interconnector and the finger electrodes overlap,
wherein the interconnector is caused to be electrically connected with the finger electrodes of the first solar cell or the finger electrodes of the second solar cell through the openings of the plurality of openings.

18. The method according to claim 17, wherein the interconnector overlaps one or more of the finger electrodes of the first solar cell or the finger electrodes of the second solar cell, and the method further comprises:
feeding the finger electrodes of the first solar cell or the finger electrodes of the second solar cell with electricity to cause metal to be deposited into the openings of the plurality of openings by way of electroplating to electrically connect the interconnector with one or more of the finger electrodes of the first solar cell or the finger electrodes of the second solar cell.

19. The method according to claim 17, wherein the interconnector comprises a core layer and a conductive material having a melting point lower than a melting point of the core layer, and the method further comprises:
heating the interconnector to cause the conductive material to melt; and
filling the openings of the plurality of openings in the insulating layer with the conductive material to electrically connect the interconnector and one or more of the finger electrodes of the first solar sell or the finger electrodes of the second solar cell.

20. A method, comprising:
forming one or more of a first solar cell or a second solar cell, wherein forming the first solar cell or the second solar cell, comprises:
forming a photoelectric conversion section comprising a substrate and a transparent electrode layer over the substrate;
forming a plurality of finger electrodes over the photoelectric conversion section, the finger electrodes of the plurality of finger electrodes being formed side by side and extending in a first direction;
forming an insulating layer over the photoelectric conversion section and the finger electrodes of the plurality of finger electrodes;
causing an interconnector and one or more of the finger electrodes of the first solar cell or the finger electrodes of the second solar cell to overlap;
heating the interconnector;
forming a plurality openings in the insulating layer at positions corresponding to where the interconnector and the finger electrodes overlap; and
causing the interconnector to be electrically connected with one or more of the finger electrodes of the first solar cell or the finger electrodes of the second solar cell based on the heating by way of the openings in the insulating layer.

21. The manufacturing method according to claim 20, the method further comprising:
arranging the interconnector on the insulating layer of the first solar cell or the second solar cell in such a manner that the interconnector has a length in a first direction along a surface of the photoelectric conversion section greater than a width in a second direction normal to the first direction along the surface of the photoelectric conversion section.

22. The method according to claim 20, wherein
the substrate comprises a first side and a second side opposite the first side,
the transparent electrode layer is a first transparent electrode layer over the first side of the substrate,
the finger electrodes are first finger electrodes over the first transparent layer,
forming one of more of the first solar cell or the second solar cell further comprises:
forming a second transparent electrode layer of the second side of the substrate;
forming a plurality of second finger electrodes over the second transparent electrode layer, the second finger electrodes of the plurality of second finger electrodes being formed side by side and extending in a third direction; and
forming a second insulating layer over the second transparent electrode layer and the second finger electrodes of plurality of second finger electrodes, and
the interconnector is caused to be electrically connected with the first finger electrodes of the first solar cell with the interconnector and the second finger electrodes of the second solar cell.

23. The crystalline silicon solar cell module according to claim 1, wherein a width of the interconnector is 50 μm or more and less than 400 μm along an in-plane direction of the first surface of the photoelectric conversion section.

24. The crystalline silicon solar cell module according to claim 1, wherein a width of the interconnector is 120 μm or more and less than 300 μm along an in-plane direction of the first surface of the photoelectric conversion section.
